(19) United States
(12) Patent Application Publication
(10) Pub. No.: US 2023/0317509 A1
(43) Pub. Date: Oct. 5, 2023

(54) SEMICONDUCTOR DEVICE AND METHOD FOR MANUFACTURING THE SAME

(71) Applicant: Silergy Semiconductor Technology (Hangzhou) LTD, Hangzhou (CN)

(72) Inventor: Huan Wang, Hangzhou (CN)

(21) Appl. No.: 18/118,243

(22) Filed: Mar. 7, 2023

(30) Foreign Application Priority Data
Mar. 22, 2022 (CN) 202210287045.6

(51) Int. Cl. H01L 21/762; H01L 21/311; H01L 21/02

(52) U.S. Cl. CPC H01L 21/76224; H01L 21/02233; H01L 21/31111

(57) ABSTRACT

A method of making a semiconductor device can include: etching a substrate to form a trench in the substrate; filling the trench with an insulating material layer, wherein a top surface of the insulating material layer is higher than a top surface of the trench; etching the insulating material layer to form a side groove between the insulating material layer and a top side wall of the trench to expose a corner at a top of the trench; and forming a field oxide layer on a top surface of the substrate by an oxidation process, wherein the corner at the top of the trench is correspondingly oxidized to form into a round corner by the oxidation process.

### RELATED APPLICATIONS

This application claims the benefit of Chinese Patent Application No. 202210287045.6, filed on Mar. 22, 2022, which is incorporated herein by reference in its entirety.

### FIELD OF THE INVENTION

The present invention generally relates to the field of semiconductor technology, and more particularly to semiconductor devices and methods of manufacturing the semiconductor devices.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. Switching power supplies have a wide variety of applications in modern electronics. For example, switching power supplies can be used to drive light-emitting diode (LED) loads. Power switches can be semiconducting devices, including metal-oxide-semiconductor field-effect transistors (MOSFETs) and insulated gate bipolar transistors (IGBTs), among others. For example, laterally-diffused metal-oxide-semiconductor (LDMOS) devices are widely used in such on-off type regulators.

### BRIEF DESCRIPTION OF THE DRAWINGS

FIG. 1 is a flow diagram of the manufacturing method of the semiconductor device, in accordance with embodiments of the present invention.

FIGS. 2A to 2H are structural diagrams of the manufacturing method of the semiconductor device, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

Semiconductor devices are generally manufactured using two complex manufacturing processes: front-end manufacturing and back-end manufacturing. Front-end manufacturing may involve the formation of a plurality of die on the surface of a semiconductor wafer. Each die on the wafer may contain active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components can be formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist may be removed, leaving behind a patterned layer. Alternatively, some types of materials can be patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface may be used to produce smaller and more densely packed active and passive components. Planarization can be used to remove material from the surface of the wafer and produce a uniformly flat surface. Planarization can involve polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer may be singulated using a laser cutting tool or saw blade. After singulation, the individual die are mounted to a package substrate that can include pins or contact pads for interconnection with other system components. Contact pads formed over the semiconductor die can then be connected to contact pads within the package. The electrical connections can be made with solder bumps, stud bumps, conductive paste, or wire bonds, as a few examples. An encapsulant or other molding material may be deposited over the package to provide physical support and electrical isolation. The finished package can then be inserted into an electrical system and the functionality of the semiconductor device is made available to the other system components.

The manufacturing process of semiconductor integrated circuits mainly includes the formation of devices such as transistors in the active region of the surface of the semiconductor substrate. These devices need to be isolated from each other through isolation structures. Both trench isolation structure and field oxide isolation structure are often used to isolate the active region of semiconductor substrate.

In making power devices (e.g., laterally-diffused metal-oxide-semiconductor [LDMOS] devices), and particularly using a local oxidation of silicon (LOCOS) process to form the field oxide layer, there are a number of different devices/designs on the junction between the high-voltage field oxide isolation structure and the shallow trench isolation structure (STI). Because of the particularity of the local oxidation process of silicon, it is relatively easy to form upward sharp corners at the junction. After the full process is completed, the sharp corners at the junction can form charge accumulation, which may reduce the actual thickness of the field oxide layer between the substrate and the polysilicon layer, thus resulting in the breakdown of the field oxide layer at the junction and reduced reliability of the field oxide layer.

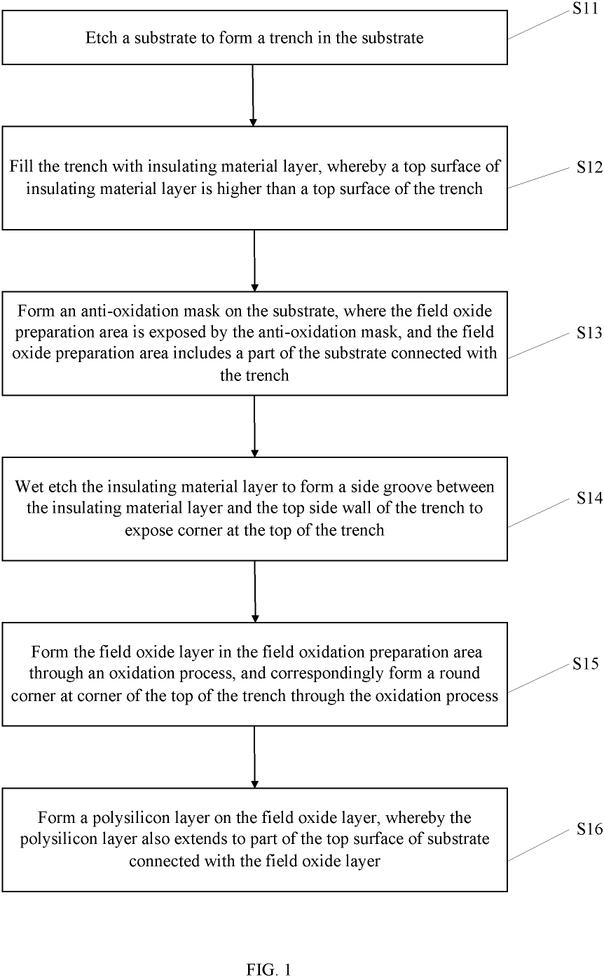

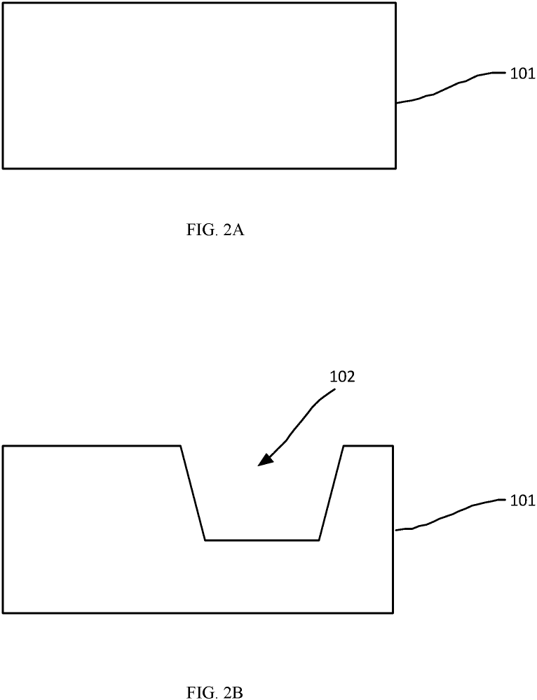

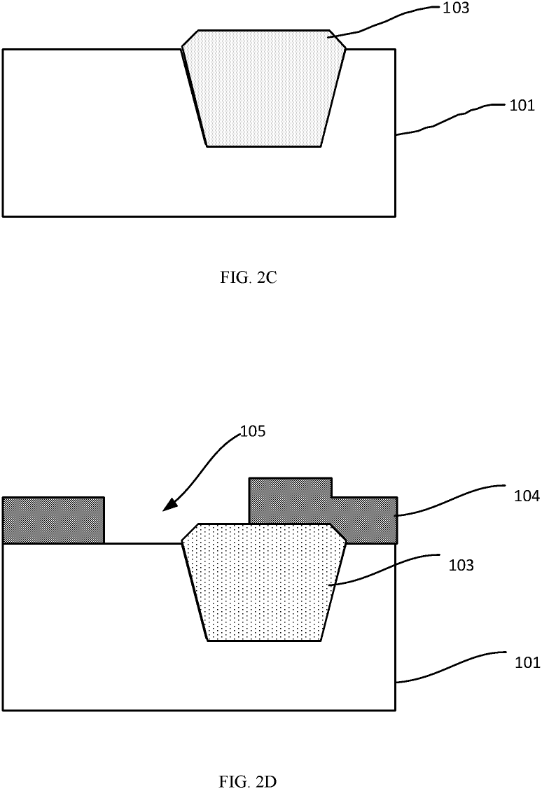

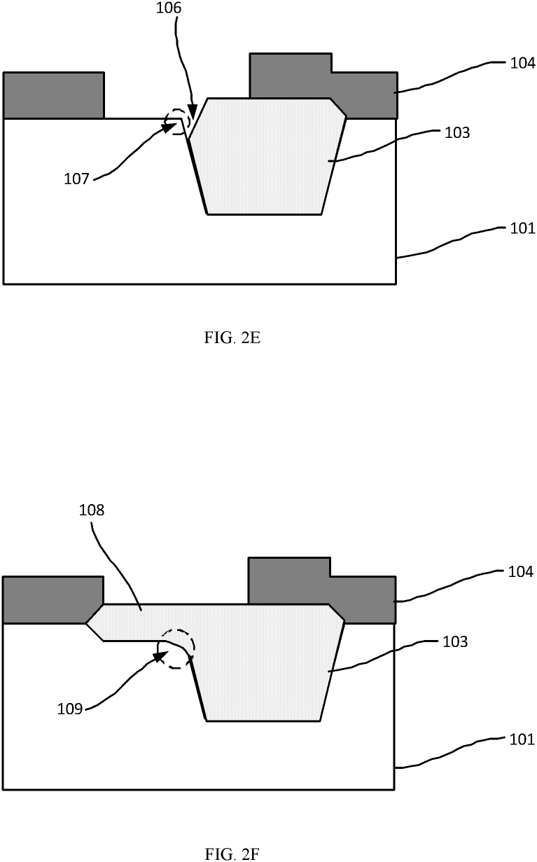

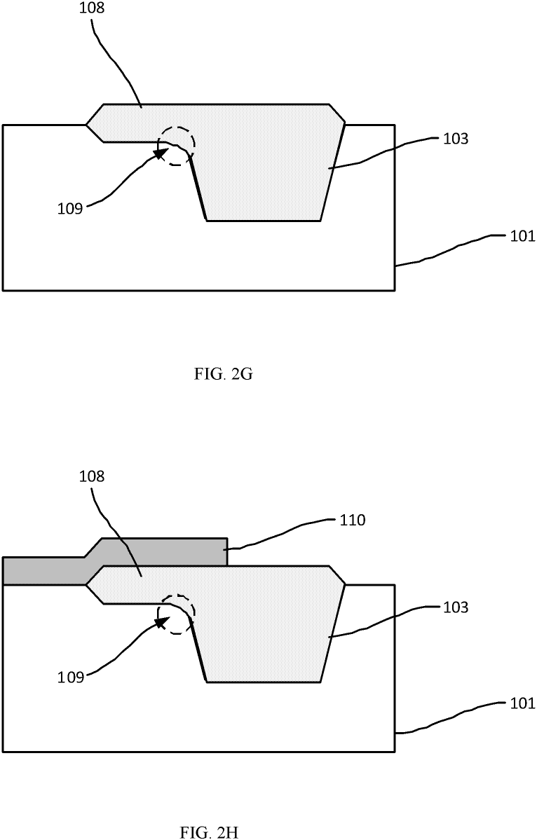

Referring now to FIG. 1, shown is a flow diagram of the manufacturing method of the semiconductor device, in accordance with embodiments of the present invention. Referring also to FIGS. 2A to 2H, shown are structural diagrams of the manufacturing method of the semiconductor device, in accordance with embodiments of the present invention. The semiconductor devices can be power devices, such as but not limited to LDMOS devices.

As shown in S11 of FIG. 1, and also referring to FIGS. 2A and 2B, substrate 101 can be provided and etched to form trench 102 in substrate 101. In one embodiment, the material of substrate 101 can include silicon. Of course, in other embodiments, the material of substrate 101 can be, e.g., germanium or silicon, and is not limited to the examples listed here. For example, the etching substrate 101 may include forming a photoresist layer on a top surface of substrate 101 by a spin coating process. In other examples, a combination of a hard mask and a photoresist layer may also be formed on the surface of substrate 101.

The photoresist layer can be patterned by an exposure process and a development process to expose the area of trench 102 to be formed. Substrate 101 can be etched by dry etching process (e.g., a reactive ion etching process, inductively coupled plasma etching process, etc.) to form trench 102 in substrate 101. If there is a hard mask, the hard mask can be etched first to transfer the pattern of the photoresist layer to the hard mask. The shape of trench 102 (e.g., a depth of trench 102 and inclination angles of the side walls of trench 102) can be adjusted by adjusting the plasma density, etching power, etching time, and/or other parameters. After the dry etching process, the photoresist layer or hard mask can be retained for subsequently filling of trench 102. In one embodiment, the side wall of trench 102 may have an inclination angle (e.g., the inclination angle is from 60 to 89 degrees, such as from 65 to 70 degrees).

As shown in S12 of FIG. 1, and also referring to FIG. 2C, trench 102 can be with insulating material layer 103, whereby a top surface of insulating material layer 103 is higher than a top surface of trench 102. In one embodiment, S12 can include using chemical vapor deposition (CVD) process is adopted, such as high-density plasma deposition (HDP), to deposit insulating material layer 103 (e.g., silicon dioxide) in trench 102. Insulating material layer 103 can be flattened by a chemical-mechanical grinding process (CMP), etc., and then the hard mask and photoresist layer in step S11 can be removed such that the top surface of insulating material layer 103 is higher than the top surface of trench 102, as shown in FIG. 2C. For example, the height of the top surface of insulating material layer 103 above the top surface of trench 102 can be between 40 nm and 60 nm.

In one embodiment, an ion implantation process can be to form wells in substrate 101. For example, the ion implantation process can include one or more of high voltage N-type well implantation, high voltage P-type well implantation, low voltage N-type well implantation, and low voltage P-type well implantation. That is, the body region and drift region can be formed in substrate 101 through an ion implantation process and other processes. Taking an N-type LDMOS as an example, the substrate is a P-type silicon substrate, the body region is a P-type doped well region, and the drift region is an N-type deep well. Using an ion implantation process to form wells in substrate 101 can also include forming a source region in the body region and forming a drain region in the drift region.

As shown in S13 of FIG. 1, and also referring to FIG. 2D, anti-oxidation mask 104 can be on substrate 101. Here, field oxide preparation area 105 may be exposed by anti-oxidation mask 104, and field oxide preparation area 105 can include a part of substrate 101 connected with trench 102. In one embodiment, forming anti-oxidation mask 104 on substrate 101 can include forming a photoresist material layer on an top surface of substrate 101 through a spin coating process. Forming anti-oxidation mask 104 can also include forming a window in the photoresist material layer through an exposure and development process to form anti-oxidation mask 104. The window may expose field oxide preparation area 105. Anti-oxidation mask 104 can isolate the oxygen on the surface of substrate 101, in order to prevent the substrate from being oxidized. Anti-oxidation mask 104 may also isolate the etching solution of the wet etching, in order to prevent other areas of substrate 101 from being etched/damaged by the corrosive solution.

As shown in S14 of FIG. 1, and also referring to FIG. 2E, insulating material layer 103 can be wet etched to form side groove 106 between insulating material layer 103 and the top side wall of trench 102, and to expose corner 107 at the top of trench 102. The etchant can be selected as an etching solution with an etching selectivity to insulating material layer 103 and substrate 101. For example, the etching selectivity of the etching solution to insulating material layer 103 and substrate 101 may be greater than 10:1, such as greater than 50:1. In one embodiment, the etching solution used for the wet etching of insulating material layer 103 can include a hydrofluoric acid solution. For example, the volume ratio of hydrofluoric acid to water can be between 1:5 and 1:100 in the hydrofluoric acid solution. The hydrofluoric acid solution may only include hydrofluoric acid and water, or may also contain other substances. For example, the etching solution can be a buffer oxide etch (BOE) solution mixed with hydrofluoric acid, ammonium fluoride, and water.

In one embodiment, a part of insulating material layer 103 may be removed by wet etching process, and the removed thickness of insulating material layer 103 can be from 200 Å to 400 Å. In one embodiment, when insulating material layer 103 is wet etched, the depth of side groove 106 may be controlled by controlling the concentration of the etchant and the time of wet etching. In this example, the depth of side groove 106 is from 200 Å to 400 Å. for example, the shape of the cross section of side groove 106 can be a V-shaped groove or a U-shaped groove. Side groove 106 can expose the side wall at the corner 107 of trench 102. In the oxidation process of S15 of FIG. 1, the side wall at the corner 107 of trench 102 and the upper surface of substrate 101 can be oxidized at substantially the same time. Thus, the oxidation rate at corner 107 can be greatly increased, such that corner 107 is oxidized into round corner 109.

As shown in S15 of FIG. 1, and also referring to FIGS. 2F and 2G, field oxide layer 108 can be formed in field oxidation preparation area 105 through an oxidation process. Correspondingly, round corner 109 can be formed at corner 107 of the top of trench 102 through the oxidation process, and removal of anti-oxidation mask 104. In one embodiment, the material of field oxide layer 108 can include silicon dioxide.

In one embodiment, substrate 101 can be heat treated in an oxygen-containing atmosphere. For example, the temperature of the oxidation process can be from 900° C. to 1100° C. For example, the oxygen-containing atmosphere can be in the air, or an additional flow of oxygen atmosphere. For example, the time of the oxidation process can be from 5 minutes to 100 minutes to form field oxide layer 108 in field oxidation preparation area 105. The side wall and upper surface of corner 107 at the top of trench 102 can be simultaneously oxidized by the oxidation process, and corner 107 may be finally oxidized to form round corner 109.

For example, the oxidation process can be carried out through a high-pressure field oxide furnace tube, and the thickness of field oxide layer 108 can be from 300 Å to 1000 Å. In one embodiment, after the forming of field oxide layer 108, side groove 106 can be completely filled due to the increase of the volume of field oxide layer 108. That is, insulating material layer 103 may be seamlessly connected with field oxide layer 108 to form an integration, in order to improve the quality of field oxide layer 108 and the trench isolation structure. In addition, corner 107 at the top of the trench may form round corner 109 due to the oxidation process.

As shown in S16 of FIG. 1, and also referring to FIG. 2H, a polysilicon layer can be formed on field oxide layer 108, and the polysilicon layer may also extend to part of the top surface of substrate 101 connected with field oxide layer 108. For example, a polysilicon layer can be formed on field oxide layer 108 through a chemical vapor deposition process, and then the polysilicon layer can be patterned through a photolithography process and an etching process, such that the polysilicon layer includes a part covering field oxide layer 108 and a part extending to the top surface of substrate 101 connected with field oxide layer 108.

As shown in FIG. 2H, particular embodiments also provide a semiconductor device formed by the manufacturing method of the semiconductor device as described herein. The semiconductor device can include substrate 101, trench 102 formed in substrate 101, insulating material layer 103 filled in trench 102, and field oxide layer 108. For example, the top surface of insulating material layer 103 can be higher than the top surface of trench 102, field oxide layer 108 may be connected with the trench 102, and corner 107 at the top of trench 102 where field oxide layer 108 is connected with trench 102 can be round corner 109.

In particular embodiments, after filling the insulating material layer in the trench, a side groove can be formed between the insulating material layer and the top side wall of the trench through the wet etching process, in order to expose the corner at the top of the trench. When the field oxide layer is subsequently formed in the field oxide preparation area through the oxidation process, the side and upper surface of the corner can be oxidized at substantially the same time, thus making the oxidation speed at the corner relatively fast, and finally eliminating the sharp corner to form a smooth corner. Particular embodiments can greatly eliminate sharp charges, and may ensure the thickness of the field oxide layer at the junction of the high-voltage field oxide isolation structure and the trench isolation structure. Thus, the breakdown voltage of the field oxide layer and the reliability of the field oxide layer can be improved.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A method of making a semiconductor device, the method comprising:
a) etching a substrate to form a trench in the substrate;
b) filling the trench with an insulating material layer, wherein a top surface of the insulating material layer is higher than a top surface of the trench;
c) etching the insulating material layer to form a side groove between the insulating material layer and a top side wall of the trench to expose a corner at a top of the trench; and
d) forming a field oxide layer on a top surface of the substrate by an oxidation process, wherein the corner at the top of the trench is correspondingly oxidized to form into a round corner by the oxidation process.

2. The method of claim 1, wherein etching the insulating material layer comprises using a wet etching process.

3. The method of claim 2, wherein an etching solution used for the wet etching of the insulating material layer comprises a hydrofluoric acid solution.

4. The method of claim 3, wherein a volume ratio of hydrofluoric acid to water in the hydrofluoric acid solution is from 1:5 to 1:100.

5. The method of claim 1, wherein during the etching of the insulating material layer, a depth of the side groove is controlled by controlling a concentration of an etching solution and a duration of a wet etching process.

6. The method of claim 5, wherein a depth of the side groove is from 200 Å to 400 Å.

7. The method of claim 1, further comprising forming an anti-oxidation mask on the substrate, wherein a field oxide preparation area is exposed by the anti-oxidation mask, and a field oxide preparation area comprises a part of the substrate that is connected with the trench.

8. The method of claim 7, wherein the forming the anti-oxidation mask on the substrate comprises:
a) forming a photoresist material layer on the substrate; and
b) forming a window in the photoresist material layer through an exposure and development process to form the anti-oxidation mask, wherein the field oxide preparation area is exposed by the window, and the anti-oxidation mask is used to isolate oxygen on the substrate surface to avoid oxidation thereof.

9. The method of claim 1, wherein the oxidation process comprises using a high pressure field oxide furnace tube, and a thickness of the field oxide layer is from 300 Å to 1000 Å.

10. The method of claim 1, wherein after the forming of the field oxide layer, the side groove is fully filled due to an increase of a volume of the field oxide layer, and the substrate at the corner of the top of the trench is oxidized to form a round corner.

11. The method of claim 7, further comprising forming a polysilicon layer on the field oxide layer, wherein the polysilicon layer extends to a part of the surface of the substrate connected with the field oxide layer.

12. The method of claim 11, further comprising removing the anti-oxidation mask before the forming of the polysilicon layer.

13. The method of claim 1, wherein the substrate comprises silicon, the insulating material layer comprises silicon dioxide, and the field oxide layer comprises silicon dioxide.

14. A semiconductor structure formed by the method of claim 1.
